(19) United States
(12) Patent Application Publication
(10) Pub. No.: US 2010/0001394 A1
(43) Pub. Date: Jan. 7, 2010

(54) CHIP PACKAGE WITH ESD PROTECTION STRUCTURE

(75) Inventors: LI PENG CHANG, HSINCHU CITY (TW); JUNG CHUN LIN, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., HSINCHU (TW)

(21) Appl. No.: 12/167,703

(22) Filed: Jul. 3, 2008

(51) Int. Cl. H01L 23/04

(52) U.S. Cl. 257/697; 257/698; 257/E23.012

(57) ABSTRACT

A chip package comprises a semiconductor chip, a plurality of pins coupled to the semiconductor chip, and a conductive structure configured to form an electrical connection between the pins, wherein the electrical connection is configured to be disabled as the chip package is inserted into a socket. Since the pins are electrically connected by the conductive structure, the surge current caused by an ESD event can be distributed to all pins rather than to a single pin as the ESD event occurs. Consequently, all ESD protection circuits connected to the pins can be used to dissipate the surge current during the ESD event, and the circuit damage caused by the ESD can be dramatically reduced.

### BACKGROUND OF THE INVENTION

(A) Field of the Invention

The present invention relates to a chip package with an electrostatic discharge (ESD) protection structure, and more particularly, to a chip package with an ESD protection structure configured to be disabled as the chip package is inserted into a socket.

(B) Description of the Related Art

Electrostatic discharges from human handling of semiconductor chip can permanently damage the semiconductor chip. During an ESD event, charge is transferred between one or more pins of the integrated circuits and another conducting object in a very short period of time, typically less than one microsecond. The charge transfer generates voltages that are high enough to break down insulating films, i.e., gate oxides in metal-oxide silicon field effect transistor (MOSFET) devices, or that can dissipate sufficient energy to cause electro-thermal failure in the MOSFET devices. Such failures include contact spiking, silicon melting, or metal interconnect melting. In general, in order to resolve the problems described above, an ESD protection circuit is generally disposed between the input and output pads of the semiconductor chip to protect the semiconductor chip from ESD damage by shunting the electrostatic charges of the ESD source from the semiconductor chip. Accordingly, researchers have invented various circuit structures for ESD protection technique such as those disclosed in U.S. Pat. No. 5,019,888, U.S. Pat. No. 4,692,781, and U.S. Pat. No. 5,001,529.

As the packing density for MOSFET devices continues to increase, they will become more susceptible to ESD induced failures. The use of thinner gate oxides, shallower source/drain junctions, and more closely spaced components simply exacerbates the problems that have been experienced in the past. It would be desirable to provide an ESD protection circuit and structure that is suitable for use with MOSFET devices and provides improved ESD protection. It would be further desirable for such a circuit and structure to be compatible with standard fabrication processes, and provide enhanced protection with little or no additional process flow complexity.

### SUMMARY OF THE INVENTION

One aspect of the present invention provides a chip package with an ESD protection structure, which is configured to form an electrical connection between the pins of the chip package that is disabled as the chip package is inserted into a socket so that the chip package can operate normally.

A chip package according to this aspect of the present invention comprises a semiconductor chip, a plurality of pins coupled to the semiconductor chip, and a conductive structure configured to form an electrical connection between the pins, wherein the electrical connection is configured to be disabled as the pins are inserted into a socket. Since the pins are electrically connected by the conductive structure, the surge current caused by the ESD event can be distributed to all pins rather than to a single pin as the ESD event occurs. Consequently, all ESD protection circuits connected to the pins can be used to dissipate the surge current during the ESD event, and the circuit damage caused by the ESD can be dramatically reduced. In other words, the ESD protection ability is enhanced. In particular, the conductive structure for the ESD protection does not change the fabrication process or the encapsulation process of the semiconductor chip; therefore, the conductive structure for the ESD protection is compatible with standard semiconductor fabrication process and provides enhanced protection with little process flow complexity.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 and FIG. 2 illustrate a chip package with an ESD protection structure according to a first embodiment of the present invention;

FIG. 3 and FIG. 4 illustrate a chip package with an ESD protection structure according to a second embodiment of the present invention; and

FIG. 5 and FIG. 6 illustrate a chip package with an ESD protection structure according to a third embodiment of the present invention.

### DETAILED DESCRIPTION OF THE INVENTION

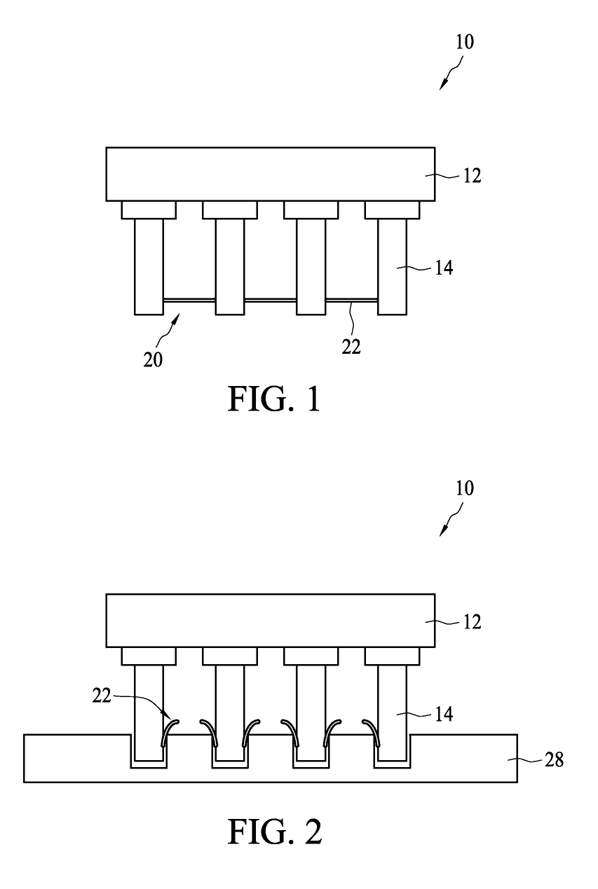

FIG. 1 and FIG. 2 illustrate a chip package 10 with an ESD protection structure according to a first embodiment of the present invention. The chip package 10 comprises a semiconductor chip 12, a plurality of pins 14 coupled to the semiconductor chip 12, and a conductive structure 20 configured to temporarily form an electrical connection between the pins 14. The semiconductor chip 12 may include ESD protection circuits (not shown in the drawings) electrically connected to each pin 14, and the ESD protection circuits can be a silicon controlled rectifiers (SCR) or those disclosed in U.S. Pat. No. 5,019,888, U.S. Pat. No. 4,692,781, and U.S. Pat. No. 5,001,529, all of which are incorporated by reference hereinto.

The conductive structure 20 may include a conductive wire 22 connecting the pins 14, i.e., the conductive wire 22 forms the electrical connection between the pins 14. Optionally, the conductive wire 22 can be divided into a plurality of conductive wires, and each conductive wire connects two pins 14. Since the pins 14 are electrically connected by the conductive wire 22 of the conductive structure 20, the surge current caused by the ESD event such as the human handling of the semiconductor chip 12 can be distributed to all pins 14 via the conductive wire 22 rather than distributed to just a single pin as the ESD event occurs. Consequently, all ESD protection circuits connected to all the pins 14 can be used to dissipate the surge current during the ESD event, and the circuit damage in the semiconductor chip 12 caused by the ESD event can be dramatically reduced, i.e., the conductive structure 20 provides an enhanced ESD protection ability.

Referring to FIG. 2, the conductive wire 22 is configured to break off by a socket 28 as the chip package 10 is inserted into the socket 28, i.e., the electrical connection is configured to be disabled as the pins 14 are inserted into the socket 28. Before the insertion of the chip package 10 into the socket 28, all the pins 14 are not independent of each other and the electrical signal can not be transmitted into or out of the semiconductor chip 12 via the pins 14 individually, i.e., the semiconductor chip 12 can not operate normally while the conductive wire 22 provides an enhanced ESD protection ability. To eliminate this problem, the conductive wire 22 is design to form the electrical connection between the pins 14 only temporarily. In particular, the conductive wire 22 breaks off and the electrical connection between the pins 14 is automatically disabled as the chip package 10 is inserted into the socket 28 such that the pins 14 become independent of each other, and the electrical signal can then be transmitted into or out of the semiconductor chip 12 via the pins 14 individually, i.e., the semiconductor chip 12 can operate normally.

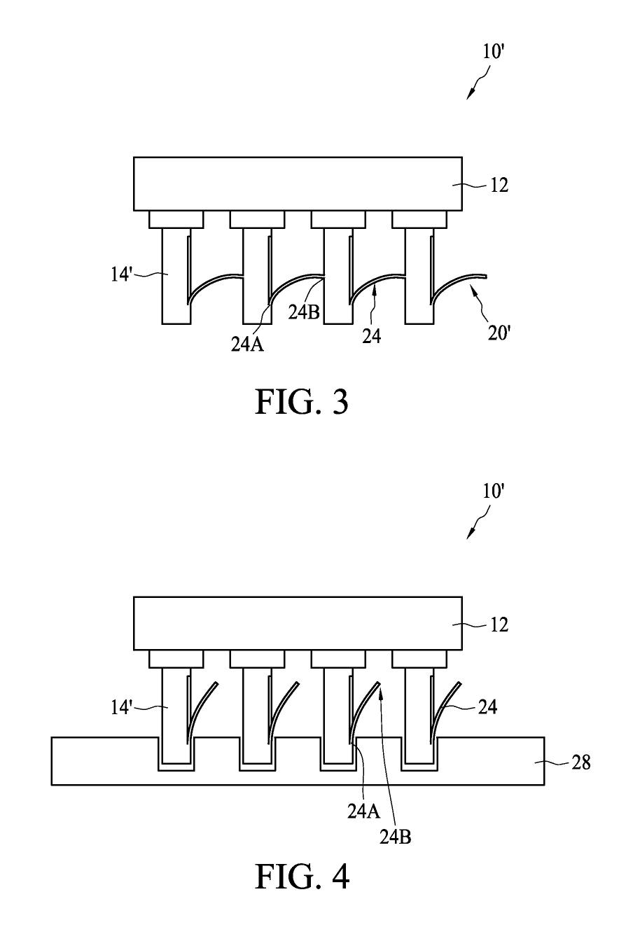

FIG. 3 and FIG. 4 illustrate a chip package 10′ with an ESD protection structure according to a second embodiment of the present invention. The chip package 10′ comprises a semiconductor chip 12, a plurality of pins 14′ coupled to the semiconductor chip 12, and a conductive structure 20′ configured to form a temporary electrical connection between the pins 14′. The semiconductor chip 12 may include ESD protection circuits (not shown in the drawings) electrically connected to the pins 14′, and the ESD protection circuits can be those disclosed in U.S. Pat. No. 5,019,888, U.S. Pat. No. 4,692,781, and U.S. Pat. No. 5,001,529, all of which are incorporated by reference hereinto.

The conductive structure 20′ may include a plurality of clip springs 24, each clip spring 24 including a first end 24A connected to one pin 14′ and a second end 24B configured to contact an adjacent pin 14′ elastically, i.e., the clip springs 24 form the electrical connection between the pins 14′. Since the pins 14′ are electrically connected by the clip springs 24 of the conductive structure 20′, the surge current caused by the ESD event such as the human handling of the semiconductor chip 12 can be distributed to all pins 14′ via the clip springs 24 rather than being distributed to just a single pin as the ESD event occurs. Consequently, all ESD protection circuits connected to all the pins 14′ can be used to dissipate the surge current during the ESD event, and the circuit damage in the semiconductor chip 12 caused by the ESD event can be dramatically reduced, i.e., the conductive structure 20′ provides an enhanced ESD protection ability.

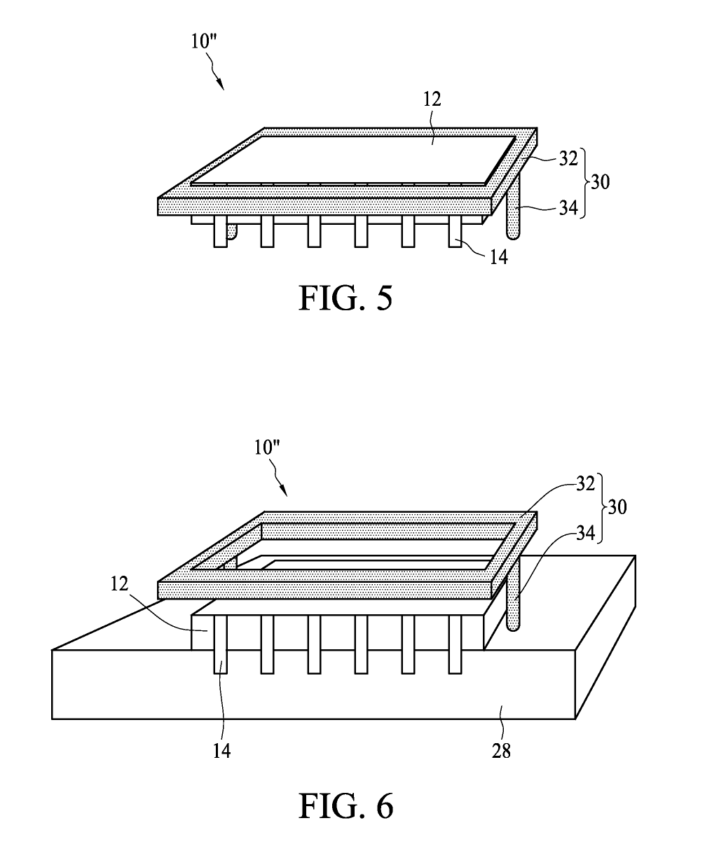

Referring to FIG. 4, the second end 24B of the clip springs 24 is configured to detach from the adjacent pin 14′ as the chip package 10′ is inserted into the socket 28. Before the insertion of the chip package 10′ into the socket 28, all the pins 14′ are not independent of each other and the electrical signal can not be transmitted into or out of the semiconductor chip 12 via the pins 14′ individually, i.e., the semiconductor chip 12 can not operate normally while the clip springs 24 provide an enhanced ESD protection ability. To eliminate this problem, the clip springs 24 are designed to only temporarily form the electrical connection between the pins 14′. In particular, the clip springs 24 detach from the adjacent pin 14′ and the electrical connection between the pins 14′ is automatically disabled as the chip package 10′ is inserted into the socket 28 such that the pins 14′ become independent of each other, and the electrical signal can then be transmitted into or out of the semiconductor chip 12 via the pins 14′ individually, i.e., the semiconductor chip 12 can operate normally. FIG. 5 and FIG. 6 illustrate a chip package 10″ with an ESD protection structure according to a third embodiment of the present invention. The chip package 10″ comprises a semiconductor chip 12, a plurality of pins 14 coupled to the semiconductor chip 12, a conductive structure 30 configured to temporarily form an electrical connection between the pins 14. The semiconductor chip 12 may include ESD protection circuits (not shown in the drawings) electrically connected to the pins 14, and the ESD protection circuits can be these disclosed in U.S. Pat. No. 5,019,888, U.S. Pat. No. 4,692,781, and U.S. Pat. No. 5,001,529, all of which are incorporated by reference hereinto.

The conductive structure 30 may include a conductive ring 32 configured to form the electrical connection between the pins 14 and a pillar 34 connected to the conductive ring 32. Since the pins 14 are electrically connected by the conductive ring 32 of the conductive structure 30, the surge current caused by the ESD event such as the human handling of the semiconductor chip 12 can be distributed to all pins 14 via the conductive ring 32 rather than being distributed to just a single pin as the ESD event occurs. Consequently, all ESD protection circuits connected to all the pins 14 can be used to dissipate the surge current during the ESD event, and the circuit damage in the semiconductor chip 12 caused by the ESD event can be dramatically reduced, i.e., the conductive structure 30 provides an enhanced ESD protection ability.

Referring to FIG. 6, the pillar 34 is configured to remove the conductive ring 32 from the pins 14 as the chip package 10″ is inserted into the socket 28. Before the insertion of the chip package 10″ into the socket 28, all the pins 14 are not independent of each other and the electrical signal can not be transmitted into or out of the semiconductor chip 12 via the pins 14 individually, i.e., the semiconductor chip 12 can not operate normally while the conductive ring 32 provides an enhanced ESD protection ability. To eliminate this problem, the conductive ring 32 is design to only temporarily form the electrical connection between the pins 14. In particular, the conductive ring 32 detaches from the pins 14 by the pillar 34 and the electrical connection between the pins 14 is automatically disabled as the chip package 10″ is inserted into the socket 28 such that the pins 14 become independent of each other, and the electrical signal can then be transmitted into or out of the semiconductor chip 12 via the pins 14 individually, i.e., the semiconductor chip 12 can operate normally.

To sum up, one feature of the present invention uses the conductive structure 20, 20′, and 30 to connect all the ESD protection circuits in the semiconductor chip 12 to dissipate the surge current during the ESD event such that an enhanced ESD protection ability is achieved. In addition, the above-mentioned conductive structure 20, 20′, and 30 for enhancing the ESD protection ability does not substantially change the fabrication process or the encapsulation process of the semiconductor chip 12; therefore, the conductive structure 20, 20′, and 30 for enhancing the ESD protection ability is compatible with standard semiconductor fabrication process and encapsulation process of the semiconductor chip 12 and provides an enhanced protection with little process flow complexity.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or combinations thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A chip package, comprising:
a semiconductor chip;
a plurality of pins coupled to the semiconductor chip;
a conductive structure configured to form an electrical connection between the pins, wherein the electrical connection is configured to be disabled as the chip package is inserted into a socket.

2. The chip package of claim 1, wherein the conductive structure includes a conductive wire connecting the pins, and the conductive wire breaks off as the pins are inserted into the socket.

3. The chip package of claim 2, wherein the conductive wire is configured to be broken off by the socket as the chip package is inserted into the socket.

4. The chip package of claim 1, wherein the conductive structure includes a plurality of conductive wires, and each conductive wire connects two pins.

5. The chip package of claim 4, wherein the conductive wires are configured to be broken off by the socket as the chip package is inserted into the socket.

6. The chip package of claim 1, wherein the conductive structure includes a conductive ring configured to form the electrical connection between the pins and a pillar connected to the conductive ring.

7. The chip package of claim 6, wherein the pillar is configured to remove the conductive ring from the pins as the chip package is inserted into the socket.

8. The chip package of claim 1, wherein the conductive structure includes a plurality of clip springs, each clip spring includes a first end connected to a first pin and a second end configured to contact a second pin elastically.

9. The chip package of claim 8, wherein the second end is configured to detach from the second pin as the chip package is inserted into the socket.

10. The chip package of claim 1, wherein the semiconductive chip includes an ESD protection circuit electrically connected to the pins.
